(19) United States
(12) Patent Application Publication
(10) Pub. No.: US 2026/0040660 A1
(43) Pub. Date: Feb. 5, 2026

(54) REVERSE-CONDUCTING INSULATED GATE BIPOLAR TRANSISTOR AND MANUFACTURING METHOD OF THE SAME

(71) Applicant: DENSO CORPORATION, Kariya-city (JP)

(72) Inventors: Toshiki KAWASE, Kariya-city (JP); Takashi KUNO, Kariya-city (JP); Eisuke ISHIKAWA, Kariya-city (JP)

(21) Appl. No.: 19/357,565

(22) Filed: Oct. 14, 2025

Related U.S. Application Data
(63) Continuation of application No. PCT/JP2024/002504, filed on Jan. 26, 2024.

(30) Foreign Application Priority Data
Apr. 18, 2023 (JP) 2023-067966

(51) Int. Cl. H10D 84/00; H10D 84/01

(52) U.S. Cl. CPC H10D 84/161; H10D 84/0109

(57) ABSTRACT

A reverse-conducting insulated gate bipolar transistor (IGBT) includes a first conductivity type boundary layer of a first conductivity type and a second conductivity type boundary layer of a second conductivity type disposed in a boundary region located between an IGBT region and a diode region. The first conductivity type boundary layer is disposed below a drift layer, and is in contact with a lower electrode. The second conductivity type boundary layer is disposed between the first conductivity type boundary layer and the drift layer.

### CROSS REFERENCE TO RELATED APPLICATIONS

The present application is a continuation application of International Patent Application No. PCT/JP2024/002504 filed on Jan. 26, 2024, which designated the U.S. and claims the benefit of priority from Japanese Patent Application No. 2023-067966 filed on Apr. 18, 2023. The entire disclosures of all of the above applications are incorporated herein by reference.

### TECHNICAL FIELD

The present disclosure relates to a reverse-conducting insulated gate bipolar transistor (IGBT) and a manufacturing method of a reverse-conducting IGBT.

### BACKGROUND

A type of semiconductor device called a reverse-conducting IGBT has been developed. A semiconductor substrate of this type of semiconductor device has an IGBT region provided with an IGBT structure and a diode region provided with a diode structure. The diode structure is connected in antiparallel to the IGBT structure and can operate as a freewheeling diode during recovery operation.

### SUMMARY

A reverse-conducting IGBT according to an aspect of the present disclosure includes a semiconductor substrate having an IGBT region, a diode region, and a boundary region located between the IGBT region and the diode region, a lower electrode disposed on a lower surface of the semiconductor substrate, and an upper electrode disposed on an upper surface of the semiconductor substrate. The semiconductor substrate includes a drift layer of a first conductivity type, a base layer of a second conductivity type, an emitter layer of the first conductivity type, a collector layer of the second conductivity type, a cathode layer of the first conductivity type. The drift layer is disposed throughout the IGBT region, the diode region, and the boundary region. The base layer is disposed throughout the IGBT region, the diode region, and the boundary region, and is disposed above the drift layer. The emitter layer is disposed in the IGBT region, is disposed above the base layer, and is in contact with the upper electrode. The collector layer is disposed in the IGBT region, is disposed below the drift layer, and is in contact with the lower electrode. The cathode layer is disposed in the diode region, is disposed below the drift layer, and is in contact with the lower electrode. The semiconductor substrate may further include a first conductivity type boundary layer of the first conductivity type and a second conductivity type boundary layer of the second conductivity type disposed in the boundary region. The first conductivity type boundary layer may be disposed below the drift layer, and may be in contact with the lower electrode. The second conductivity type boundary layer of the second conductivity type may be disposed in the boundary region, and may be disposed between the first conductivity type boundary layer and the drift layer.

### BRIEF DESCRIPTION OF DRAWINGS

Objects, features and advantages of the present disclosure will become apparent from the following detailed description made with reference to the accompanying drawings. In the drawings:

FIG. 1 is a plan layout view of a semiconductor device according an embodiment of the present disclosure and schematically shows a plan layout for explaining a layout of an IGBT region, a diode region, and a boundary region;

FIG. 2 is a partial cross-sectional view of the semiconductor device taken along line II-II in FIG. 1 and schematically shows a portion of the semiconductor device including the IGBT region, the diode region, and the boundary region;

FIG. 3 is a diagram showing a flow of forming a collector layer, a cathode layer, an n-type boundary layer, and a p-type boundary layer in a manufacturing method of the semiconductor device;

FIG. 4 is a partial cross-sectional view of a semiconductor device according to a modification of the embodiment, taken along a line corresponding to line II-II in FIG. 1; and

FIG. 5 is a partial cross-sectional view of a semiconductor device according to another modification of the embodiment, taken along a line corresponding to line II-II in FIG. 1.

### DETAILED DESCRIPTION

Next, relevant technology is described to facilitate understanding of the following embodiments. In a semiconductor device referred to as a reverse-conducting IGBT, during recovery operation, holes are injected obliquely from a p-type base layer in a IGBT region toward an n-type cathode layer in a diode region. When the amount of holes injected obliquely from the p-type base layer toward the n-type cathode layer increases, a recovery current increases and a recovery loss also increases. Therefore, in this type of semiconductor device, a boundary region may be disposed between the IGBT region and the diode region. In the boundary region, a p-type collector layer may be formed to extend from the IGBT region. In such a configuration, since a diode structure is not formed in the boundary region, the amount of holes injected obliquely from the p-type base layer toward the n-type cathode layer during recovery operation is suppressed.

When the p-type collector layer is disposed in the boundary region, holes are injected from the p-type collector layer in the boundary region into the n-type drift layer in the boundary region while the IGBT structure is in the on-state. When the IGBT structure is turned off, the holes injected into the drift layer in the boundary region move obliquely toward the p-type base layer in the IGBT region and are discharged via the p-type base layer. Therefore, there is concern that a time required for the holes to be discharged becomes longer, and switching loss will increase due to the increase in an tail current.

According to a first aspect of the present disclosure, a reverse-conducting IGBT includes a semiconductor substrate having an IGBT region, a diode region, and a boundary region located between the IGBT region and the diode region, a lower electrode disposed on a lower surface of the semiconductor substrate, and an upper electrode disposed on an upper surface of the semiconductor substrate. The semiconductor substrate includes a drift layer of a first conductivity type, a base layer of a second conductivity type, an emitter layer of the first conductivity type, a collector layer of the second conductivity type, a cathode layer of the first conductivity type, a first conductivity type boundary layer of the first conductivity type, and a second conductivity type boundary layer of the second conductivity type. The drift layer is disposed throughout the IGBT region, the diode region, and the boundary region. The base layer is disposed throughout the IGBT region, the diode region, and the boundary region, and is disposed above the drift layer. The emitter layer is disposed in the IGBT region, is disposed above the base layer, and is in contact with the upper electrode. The collector layer is disposed in the IGBT region, is disposed below the drift layer, and is in contact with the lower electrode. The cathode layer is disposed in the diode region, is disposed below the drift layer, and is in contact with the lower electrode. The first conductivity type boundary layer is disposed in the boundary region, is disposed below the drift layer, and is in contact with the lower electrode. The second conductivity type boundary layer is disposed in the boundary region, and is disposed between the first conductivity type boundary layer and the drift layer. In the present disclosure, the expressions “disposed above” and “disposed below” merely specify a positional relationship between two semiconductor layers in the vertical direction of the semiconductor substrate. For example, the two semiconductor layers may be arranged in contact with each other, or another semiconductor layer may be interposed between the two semiconductor layers. In addition, the terms “first conductivity type” and “second conductivity type” are used to indicate that the conductivity types are different. For example, the “first conductivity type” may be n-type and the “second conductivity type” may be p-type.

In the reverse-conducting IGBT according to the first aspect, the first conductivity type boundary layer and the second conductivity type boundary layer are disposed in the lower portion of the boundary region of the semiconductor substrate. Since the second conductivity type boundary layer is disposed in the boundary region, the amount of carriers injected obliquely from the base layer in the IGBT region toward the cathode layer in the diode region during the recovery operation can be suppressed. Furthermore, since the first conductivity type boundary layer is disposed in the boundary region, the amount of carriers injected into the drift layer in the boundary region while the IGBT structure in the IGBT region is in the on-state can be suppressed. Therefore, in the reverse-conducting IGBT according to the first aspect, an increase in switching loss can be suppressed.

According to a second aspect of the present disclosure, a manufacturing method of a reverse-conducting IGBT is provided. The reverse-conducting IGBT includes a semiconductor substrate having an IGBT region, a diode region, and a boundary region located between the IGBT region and the diode region. The manufacturing method includes a first ion implantation process and a second ion implantation process. The first ion implantation process includes implanting second conductivity type impurity ions into portions of the semiconductor substrate corresponding to the IGBT region and the boundary region in a lower portion of the semiconductor substrate. The second ion implantation process includes implanting first conductivity type impurity ions into portions of the semiconductor substrate corresponding to the diode region and the boundary region in the lower portion of the semiconductor substrate. A concentration of the second conductivity type impurity ions implanted in the first ion implantation process and a concentration of the first conductivity type impurity ions implanted in the second ion implantation process are adjusted in such a manner that the concentration of the first conductivity type impurity ions is higher than the concentration of the second conductivity type impurity ions at a first portion of the semiconductor substrate close to a lower surface of the semiconductor substrate, and the concentration of the second conductivity type impurity ions is higher than the concentration of the first conductivity type impurity ions at a second portion of the semiconductor substrate that is further from the lower surface of the semiconductor substrate than the first portion.

According to the manufacturing method according to the second aspect, by performing two ion implantation processes, a collector layer containing the second conductivity type impurity ions can be formed in the IGBT region of the semiconductor substrate, a collector layer containing the first conductivity type impurity ions can be formed in the diode region of the semiconductor substrate, a first conductivity type boundary layer can be formed in the first portion in the boundary region of the semiconductor substrate close to the lower surface of the semiconductor substrate, and a second conductivity type boundary layer can be formed in the second portion in the boundary region farther from the lower surface than the first portion. The manufacturing method according to the second aspect can form multiple layers, the number of which exceeds the number of ion implantation processes.

Hereinafter, a semiconductor device according to an embodiment of the present embodiment will be described with reference to the drawings. It should be noted that, for the purpose of clarifying the drawings, reference numerals are assigned only to one of repeatedly arranged components, and reference numerals for the other components are omitted.

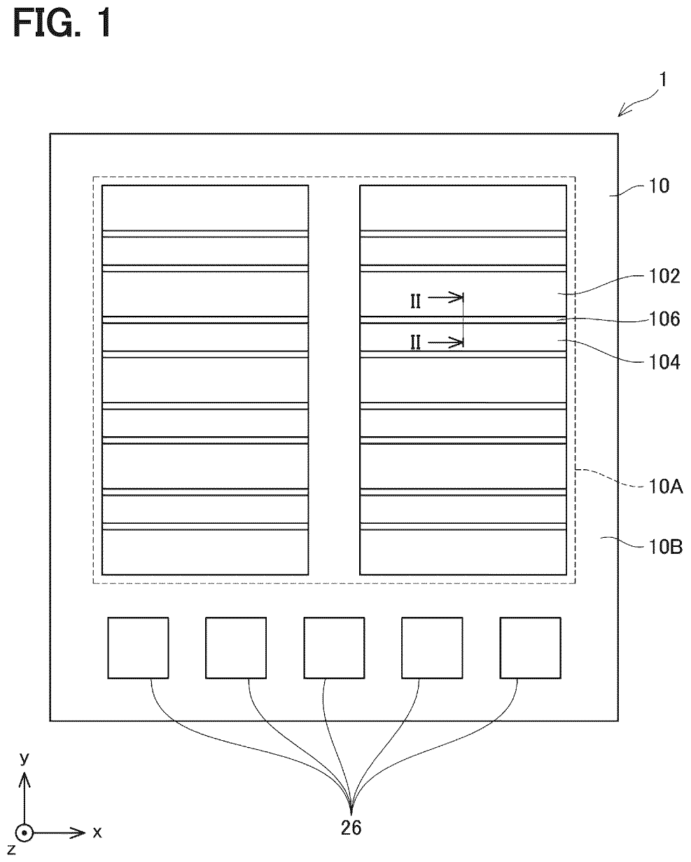

FIG. 1 schematically shows a plan layout view of a semiconductor device 1 according to the present embodiment. The semiconductor device 1 is a type of semiconductor device called a reverse-conducting IGBT, and is manufactured using a semiconductor substrate 10. The semiconductor substrate 10 has an element region 10A and a termination region 10B located around the element region 10A. The element region 10A of the semiconductor substrate 10 is divided into an IGBT region 102 having an IGBT structure, a diode region 104 having a diode structure, and a boundary region 106 located between the IGBT region 102 and the diode region 104. When viewed from a direction perpendicular to an upper surface of the semiconductor substrate 10 (hereinafter referred to as “in plan view of the semiconductor substrate 10”), the IGBT region 102 and the diode region 104 are alternately and repeatedly arranged along one direction (in this example, a y-direction) within the element region 10A. A termination structure for high breakdown voltage such as a guard ring is formed within a region of the semiconductor substrate 10 corresponding to the termination region 10B. Furthermore, small signal pads 26 are disposed within a region of the upper surface of the semiconductor substrate 10 corresponding to the termination region 10B. The small signal pads 26 may include, for example, a gate pad for inputting a gate signal, a temperature sense pad for outputting a temperature sense signal, and a current sense pad for outputting a current sense signal.

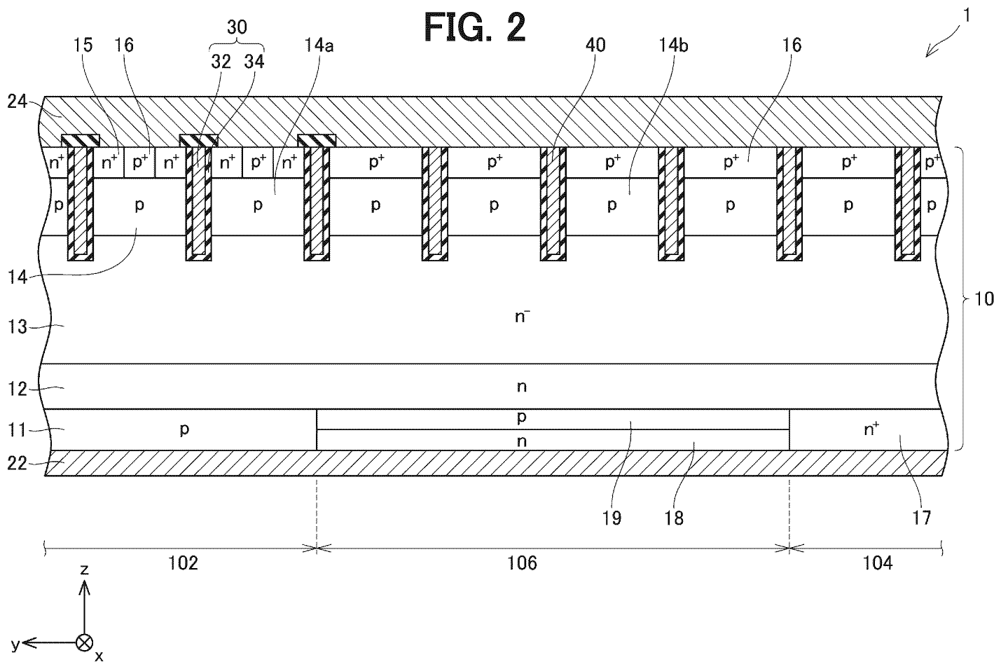

FIG. 2 is a partial cross-sectional view of the semiconductor device 1 taken along line II-II in FIG. 1. As shown in FIG. 2, the semiconductor device 1 includes the semiconductor substrate 10, which is a silicon substrate, a collector electrode 22 (an example of a lower electrode) disposed so as to cover a lower surface of the semiconductor substrate 10, an emitter electrode 24 (an example of an upper electrode) disposed so as to cover an upper surface of the semiconductor substrate 10, a plurality of trench gates 30 disposed in a upper layer portion of the semiconductor substrate 10, and a plurality of dummy trench gates 40 disposed in the upper layer portion of the semiconductor substrate 10.

The semiconductor substrate 10 includes a p-type collector layer 11, an n-type buffer layer 12, an n⁻-type drift layer 13, a p-type base layer 14, a plurality of n⁺-type emitter layers 15, a plurality of p⁺-type contact layers 16, an n⁺-type cathode layer 17, an n-type boundary layer 18, and a p-type boundary layer 19.

The collector layer 11 is disposed in a region corresponding to the IGBT region 102 in the lower portion of the semiconductor substrate 10, and is formed at a position exposed on the lower surface of the semiconductor substrate 10. The collector layer 11 is in ohmic contact with the collector electrode 22 that covers the lower surface of the semiconductor substrate 10. The collector layer 11 is formed by implanting ions of a p-type impurity toward the lower surface of the semiconductor substrate 10 using ion implantation techniques. The collector layer 11 may be formed by multiple ion implantation processes and may have a plurality of peak concentrations in a thickness direction of the semiconductor substrate 10. The p-type impurity is not particularly limited, and may be, for example, boron. A peak concentration of the p-type impurity contained in the collector layer 11 is not particularly limited, and may be, for example, in the range of 1×10¹⁶ cm⁻³ to 1×10¹⁸ cm⁻³.

The buffer layer 12 is disposed throughout the IGBT region 102, the boundary region 106, and the diode region 104 of the semiconductor substrate 10. In the IGBT region 102, the buffer layer 12 is disposed between the collector layer 11 and the drift layer 13 to separate the collector layer 11 from the drift layer 13, with a lower surface of the buffer layer 12 in contact with the collector layer 11 and an upper surface of the buffer layer 12 in contact with the drift layer 13. In the boundary region 106, the buffer layer 12 is disposed between the p-type boundary layer 19 and the drift layer 13 to separate the p-type boundary layer 19 from the drift layer 13 with the lower surface of the buffer layer 12 in contact with the p-type boundary layer 19 and the upper surface of the buffer layer 12 in contact with the drift layer 13. In the diode region 104, the buffer layer 12 is disposed between the cathode layer 17 and the drift layer 13 to separate the cathode layer 17 from the drift layer 13, with the lower surface of the buffer layer 12 in contact with the cathode layer 17 and the upper surface of the buffer layer 12 in contact with the drift layer 13. The buffer layer 12 is a layer having a higher concentration of n-type impurity ions than the drift layer 13. The buffer layer 12 is formed by implanting ions of an n-type impurity toward the lower surface of the semiconductor substrate 10 using ion implantation techniques. The n-type impurity is not particularly limited, and may be, for example, phosphorus. A peak concentration of the n-type impurity contained in the buffer layer 12 is not particularly limited, and may be, for example, from 1×10¹⁵ cm⁻³ to 1×10¹⁸ cm⁻³.

The drift layer 13 is disposed throughout the IGBT region 102, the boundary region 106, and the diode region 104 of the semiconductor substrate 10. The drift layer 13 is disposed between the buffer layer 12 and the base layer 14 to separate the buffer layer 12 and the base layer 14, with a lower surface of the drift layer 13 in contact with the buffer layer 12 and an upper surface of the drift layer 13 in contact with the base layer 14. The drift layer 13 is a remaining portion within the semiconductor substrate 10 after other semiconductor layers have been formed. A peak concentration of the n-type impurity contained in the drift layer 13 is not particularly limited, and may be, for example, from 1×10¹³ cm⁻³ to 1×10¹⁵ cm⁻³.

The base layer 14 is disposed throughout the IGBT region 102, the boundary region 106, and the diode region 104 of the semiconductor substrate 10. In the IGBT region 102, the base layer 14 is disposed between the drift layer 13 and the emitter layer 15 and the contact layer 16 to separate the drift layer 13 from the emitter layer 15 and the contact layer 16, with a lower surface of the base layer 14 in contact with the drift layer 13 and an upper surface of the base layer 14 in contact with the emitter layer 15 and the contact layer 16. In the boundary region 106 and the diode region 104, the base layer 14 is disposed between the drift layer 13 and the contact layer 16 to separate the drift layer 13 from the contact layer 16, with the lower surface of the base layer 14 in contact with the drift layer 13 and the upper surface of the base layer 14 in contact with the contact layer 16. The base layer 14 is formed by implanting ions of a p-type impurity toward the upper surface of the semiconductor substrate 10 using ion implantation techniques. The p-type impurity is not particularly limited, and may be, for example, boron. A peak concentration of the p-type impurity contained in the base layer 14 is not particularly limited, and may be, for example, in the range of 1×10¹⁵ cm⁻³ to 1×10¹⁷ cm⁻³.

In this example, the base layer 14 further includes a first base layer 14a and a second base layer 14b. The first base layer 14a is a portion of the base layer 14 that is disposed in a region corresponding to the IGBT region 102 of the semiconductor substrate 10. The second base layer 14b is a portion of the base layer 14 that is disposed in a region corresponding to the diode region 104 and the boundary region 106 of the semiconductor substrate 10. The first base layer 14a and the second base layer 14b are disposed at the same depth range within the semiconductor substrate 10. A concentration of the p-type impurity in the first base layer 14a is adjusted such that a gate threshold voltage of the trench gates 30 attain a desired value. A concentration of the p-type impurity in the second base layer 14b is adjusted to control the amount of holes injected during the recovery operation. Therefore, the concentration of the p-type impurity in the second base layer 14b is lower than the concentration of the p-type impurity in the first base layer 14a.

Each of the emitter layers 15 is partially disposed in a region of the upper portion of the semiconductor substrate 10 corresponding to the IGBT region 102, and is disposed at a position exposed on the upper surface of the semiconductor substrate 10. Each of the plurality of emitter layers 15 is in contact with a side surface of the corresponding trench gate 30, and is in ohmic contact with the emitter electrode 24 that covers the upper surface of the semiconductor substrate 10. Each of the plurality of emitter layers 15 is selectively formed in the IGBT region 102 of the semiconductor substrate 10, and is not formed in the diode region 104 and the boundary region 106 of the semiconductor substrate 10. In other words, the region of the semiconductor substrate 10 where the emitter layers 15 are disposed constitutes the IGBT region 102. Each of the emitter layers 15 is formed by implanting ions of an n-type impurity toward the upper surface of the semiconductor substrate 10 using ion implantation techniques. The n-type impurity is not particularly limited, and may be, for example, phosphorus. A peak concentration of the n-type impurity contained in each of the emitter layers 15 is not particularly limited, and may be, for example, in the range of 1×10¹⁸ cm⁻³ to 1×10²⁰ cm⁻³. In the present disclosure, the layout of the emitter layers 15 formed in the upper layer portion of the semiconductor substrate 10 is not particularly limited, and various layouts may be adopted.

The contact layers 16 are partially disposed across the IGBT region 102, the boundary region 106, and the diode region 104 of the semiconductor substrate 10, and are disposed at positions exposed on the upper surface of the semiconductor substrate 10. Each of the contact layers 16 is in ohmic contact with the emitter electrode 24 that covers the upper surface of the semiconductor substrate 10. Each of the contact layers 16 is formed by implanting ions of a p-type impurity toward the upper surface of the semiconductor substrate 10 using ion implantation techniques. The p-type impurity is not particularly limited, and may be, for example, boron. A peak concentration of the p-type impurity contained in each of the contact layers 16 is not particularly limited, and may be, for example, in the range of 1×10¹⁷ cm⁻³ to 1×10²⁰ cm⁻³. In the present disclosure, the layout of the contact layers 16 formed in the upper layer portion of the semiconductor substrate 10 is not particularly limited, and various layouts may be adopted.

The cathode layer 17 is disposed in a region of the lower portion of the semiconductor substrate 10 corresponding to the diode region 104, and is formed at a position exposed on the lower surface of the semiconductor substrate 10. The cathode layer 17 is in ohmic contact with the collector electrode 22 that covers the lower surface of the semiconductor substrate 10. The cathode layer 17 is selectively formed in the diode region 104 of the semiconductor substrate 10, and is not formed in the IGBT region 102 and the boundary region 106 of the semiconductor substrate 10. In other words, the region of the semiconductor substrate 10 where the cathode layer 17 is disposed constitutes the diode region 104. The cathode layer 17 is formed by implanting ions of an n-type impurity toward the lower surface of the semiconductor substrate 10 using ion implantation techniques. The cathode layer 17 may be formed by multiple ion implantation processes and may have a plurality of peak concentrations in the thickness direction of the semiconductor substrate 10. The n-type impurity is not particularly limited, and may be, for example, phosphorus. A peak concentration of the n-type impurity contained in the cathode layer 17 is not particularly limited, and may be, for example, in the range of 1×10¹⁸ cm⁻³ to 1×10²⁰ cm⁻³.

The n-type boundary layer 18 is disposed in a region in the lower portion of the semiconductor substrate 10 corresponding to the boundary region 106, and is arranged at a position exposed on the lower surface of the semiconductor substrate 10. An end of the n-type boundary layer 18 adjacent to the IGBT region 102 is in contact with the collector layer 11, and an end of the n-type boundary layer 18 adjacent to the diode region 104 is in contact with the cathode layer 17. The n-type boundary layer 18 is disposed between the collector electrode 22 and the p-type boundary layer 19 to separate the collector electrode 22 from the p-type boundary layer 19, with a lower surface of the n-type boundary layer 18 in contact with the collector electrode 22 and an upper surface of the n-type boundary layer 18 in contact with the p-type boundary layer 19. The n-type boundary layer 18 is in ohmic contact with the collector electrode 22 that covers the lower surface of the semiconductor substrate 10. The n-type boundary layer 18 is formed by implanting ions of an n-type impurity toward the lower surface of the semiconductor substrate 10 using ion implantation techniques. The n-type impurity is not particularly limited, and may be, for example, phosphorus. A peak concentration of the n-type impurity contained in the n-type boundary layer 18 is not particularly limited, and may be, for example, in the range of 1×10¹⁸ cm⁻³ to 1×10²⁰ cm⁻³.

The p-type boundary layer 19 is disposed in a region in the lower portion of the semiconductor substrate 10 corresponding to the boundary region 106. An end of the p-type boundary layer 19 adjacent to the IGBT region 102 is in contact with the collector layer 11, and an end of the p-type boundary layer 19 adjacent to the diode region 104 is in contact with the cathode layer 17. The p-type boundary layer 19 is disposed between the n-type boundary layer 18 and the buffer layer 12 to separate the n-type boundary layer 18 from the buffer layer 12, with a lower surface of the p-type boundary layer 19 in contact with the n-type boundary layer 18 and an upper surface of the p-type boundary layer 19 in contact with the buffer layer 12. The p-type boundary layer 19 is formed by implanting ions of a p-type impurity toward the lower surface of the semiconductor substrate 10 using ion implantation techniques. The p-type impurity is not particularly limited, and may be, for example, boron. A peak concentration of the p-type impurity contained in the p-type boundary layer 19 is not particularly limited, and may be, for example, in the range of 1×10¹⁶ cm⁻³ to 1×10¹⁸ cm⁻³.

The trench gates 30 are disposed in respective trenches formed in a region in the upper portion of the semiconductor substrate 10 corresponding to the IGBT region 102. Each of the trench gates 30 has a gate electrode 32 and a gate insulating film 34. The gate electrode 32 is insulated from the semiconductor substrate 10 by the gate insulating film 34, and is insulated from the emitter electrode 24 by an interlayer insulating film. Each of the trench gates 30 penetrates through the base layer 14 from the upper surface of the semiconductor substrate 10 and reaches the drift layer 13. In this example, the trench gates 30 extend along the x-direction when viewed in plan from above the semiconductor substrate 10, and are arranged spaced apart from each other in the y-direction. That is, the trench gates 30 are arranged at intervals along the direction in which the IGBT region 102 and the diode region 104 are repeatedly arranged, when viewed in plan from above the semiconductor substrate 10, and have a stripe-shaped layout. In another example, the trench gates 30 may have other types of layouts.

The dummy trench gates 40 are disposed in respective trenches formed in a region in the upper portion of the semiconductor substrate 10 corresponding to the diode region 104 and the boundary region 106. The dummy trench gates 40 are formed in the same manufacturing process as the trench gates 30, but differ from the trench gates 30 in that the interlayer insulating film, which insulates the gate electrode 32 from the emitter electrode 24, is omitted. The dummy trench gates 40 have the same layout as the trench gates 30. In a case where the dummy trench gates 40 described above are disposed, it is possible to alleviate electric field concentration in the diode region 104 and the boundary region 106.

The semiconductor device 1 can control the turning on and off of the current flowing through the IGBT region 102 from the collector electrode 22 to the emitter electrode 24, based on the gate voltage applied to the gate electrodes 32 of the trench gates 30. Furthermore, in the semiconductor device 1, the diode structure formed in the diode region 104 can operate as a freewheeling diode during recovery operation.

During the recovery operation in which the diode structure operates, if the amount of holes injected obliquely from the p-type base layer 14 in the IGBT region 102 toward the n-type cathode layer 17 in the diode region 104 increases, the recovery current increases and the recovery loss also increases. In the semiconductor device 1, since the p-type boundary layer 19 is disposed in the boundary region 106, the distance between the p-type base layer 14 in the IGBT region 102 and the n-type cathode layer 17 in the diode region 104 becomes longer. Therefore, the amount of holes injected obliquely during the recovery operation is suppressed, and the recovery current is reduced. Accordingly, the semiconductor device 1 can have characteristics of low recovery loss.

It should be noted that a width of the boundary region 106, measured along a direction connecting the IGBT region 102 and the diode region 104, is adjusted to a size necessary to suppress the amount of holes injected obliquely. The width of the boundary region 106 is not particularly limited, and may be, for example, 0.5 μm or more, and preferably 1.0 μm or more. In addition, the width of the boundary region 106 may be greater than a width between adjacent dummy trench gates 40 (that is, a pitch width of the dummy trench gates 40). The width of the boundary region 106 may be greater than the substrate thickness of the semiconductor substrate 10. It should be noted that, in order to reduce area consumption, the width of the boundary region 106 may be smaller than twice the substrate thickness of the semiconductor substrate 10.

Here, consider a case where the n-type boundary layer 18 is not disposed in the boundary region 106, and only the p-type boundary layer 19 is disposed. In this case, when the IGBT structure is in the on-state, holes are injected from the p-type boundary layer 19 in the boundary region 106 toward the n-type drift layer 13 in the boundary region 106. When the IGBT structure is turned off, the holes injected into the drift layer 13 move obliquely toward the p-type base layer 14 in the IGBT region 102 and are discharged through the p-type base layer 14. As a result, the time required for the holes to be discharged becomes longer, leading to an increase in switching loss due to the increase in an tail current.

In the semiconductor device 1, the n-type boundary layer 18 is disposed in the boundary region 106. The n-type boundary layer 18 is disposed between the collector electrode 22 and the p-type boundary layer 19 to separate the collector electrode 22 from the p-type boundary layer 19. Thus, when the IGBT structure is in the on-state, the amount of holes injected from the p-type boundary layer 19 in the boundary region 106 into the n-type drift layer 13 is suppressed. Accordingly, the semiconductor device 1 can exhibit characteristics of low switching loss.

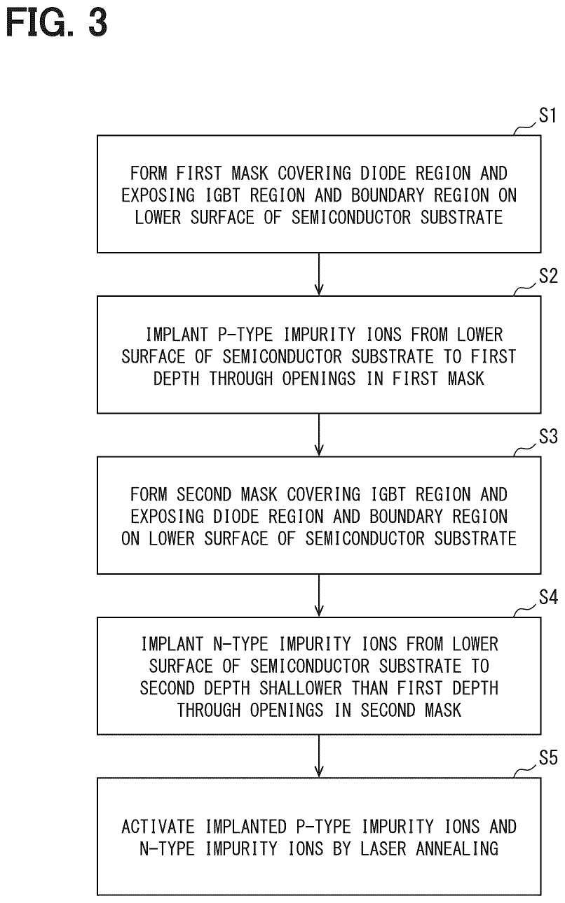

Next, with reference to FIG. 3, a description will be given of processes of forming the collector layer 11, the cathode layer 17, the n-type boundary layer 18, and the p-type boundary layer 19 in a manufacturing method of the semiconductor device 1. For processes in the manufacturing method of the semiconductor device 1 other than those described below, known processes may be employed.

First, using photolithography techniques, a first mask is formed on the lower surface of the semiconductor substrate 10 (see S1). The first mask is patterned so as to cover the diode region 104 while exposing the IGBT region 102 and the boundary region 106 on the lower surface of the semiconductor substrate 10.

Next, using ion implantation techniques, ions of the p-type impurity are implanted into regions in the lower layer portion of the semiconductor substrate 10 corresponding to the IGBT region 102 and the boundary region 106, through openings of the first mask (see S2). The ions of the p-type impurity are implanted to a first depth from the lower surface of the semiconductor substrate 10. The first mask is removed after the ion implantation.

Next, using photolithography techniques, a second mask is formed on the lower surface of the semiconductor substrate 10 (see S3). The second mask is patterned so as to cover the IGBT region 102 while exposing the diode region 104 and the boundary region 106 on the lower surface of the semiconductor substrate 10.

Next, using ion implantation techniques, ions of the n-type impurity are implanted into regions in the lower layer portion of the semiconductor substrate 10 corresponding to the diode region 104 and the boundary region 106, through openings of the second mask (see S4). The ions of the n-type impurity are implanted from the lower surface of the semiconductor substrate 10 to a second depth. Here, comparing the first depth in S2 with the second depth in S4, the second depth is shallower than the first depth. The second mask is removed after the ion implantation.

Next, laser annealing is performed by irradiating the lower surface of the semiconductor substrate 10 with a laser (see S5). As a result, the p-type impurity ions and the n-type impurity ions introduced into the lower layer portion of the semiconductor substrate 10 are activated. Through these processes, it is possible to form the collector layer 11, the cathode layer 17, the n-type boundary layer 18, and the p-type boundary layer 19 in the lower layer portion of the semiconductor substrate 10. It should be noted that the processes at S1 and S2 may be carried out after the processes at S3 and S4.

According to this manufacturing method, both the n-type impurity and the p-type impurity are implanted into the region corresponding to the boundary region 106 in the lower layer portion of the semiconductor substrate 10. The p-type impurity is implanted to the first depth that is relatively deep, while the n-type impurity is implanted to the second depth that is relatively shallow. A peak concentration of the p-type impurity at the first depth is greater than a concentration of the n-type impurity at the first depth. A peak concentration of the n-type impurity at the second depth is greater than a concentration of the p-type impurity at the second depth. The laser annealing can activate the implanted impurities without causing significant diffusion. Therefore, the n-type impurity and the p-type impurity after activation can also maintain the above concentration distribution. As a result, in the boundary region 106 of the semiconductor substrate 10, the n-type boundary layer 18 is formed at a first portion close to the lower surface of the semiconductor substrate 10, and the p-type boundary layer 19 is formed at a second portion farther from the lower surface of the semiconductor substrate 10 than the first portion.

According to the above manufacturing method, using two masks, that is, the first mask and the second mask, the collector layer 11 containing the p-type impurity can be formed in the IGBT region 102 of the semiconductor substrate 10, the cathode layer 17 containing the n-type impurity can be formed in the diode region 104 of the semiconductor substrate 10, and a stacked portion of the n-type boundary layer 18 and the p-type boundary layer 19 can be formed in the boundary region 106 of the semiconductor substrate 10. The above-described manufacturing method can form multiple layers, the number of which exceeds the number of ion implantation processes.

In the above-described manufacturing method, ions of the p-type impurity are simultaneously implanted through the first mask into both the IGBT region 102 and the boundary region 106 in the lower layer portion of the semiconductor substrate 10. Therefore, the distribution of the p-type impurity in the thickness direction of the semiconductor substrate 10 is the same in both the stacked portion of the n-type boundary layer 18 and the p-type boundary layer 19 and the collector layer 11. Similarly, in the above-described manufacturing method, ions of the n-type impurity are simultaneously implanted through the second mask into both the diode region 104 and the boundary region 106 in the lower layer portion of the semiconductor substrate 10. Therefore, the distribution of the n-type impurity in the thickness direction of the semiconductor substrate 10 is the same in both the stacked portion of the n-type boundary layer 18 and the p-type boundary layer 19 and the cathode layer 17. The above-described concentration distribution is one of the characteristics resulting from the application of the above-described manufacturing method.

In addition, in the above-described manufacturing method, both the n-type impurity and the p-type impurity are implanted into the boundary region 106 in the lower layer portion of the semiconductor substrate 10. The second portion with a relatively higher concentration of the p-type impurity becomes the p-type boundary layer 19, and the first portion with the relatively higher concentration of the n-type impurity becomes the n-type boundary layer 18. Therefore, an effective peak concentration of the n-type impurity in the n-type boundary layer 18 is smaller than an effective peak concentration of the n-type impurity in the cathode layer 17. Similarly, an effective peak concentration of the p-type impurity in the p-type boundary layer 19 is smaller than an effective peak concentration of the p-type impurity in the collector layer 11. Such a relationship in the effective peak concentrations of impurities is one of the characteristics resulting from the application of the above-described manufacturing method. In addition, in the above-described manufacturing method, the depth of the upper surface of the collector layer 11 coincides with the depth of the upper surface of the p-type boundary layer 19. Such a positional relationship is also one of the characteristics resulting from the application of the above-described manufacturing method.

In the above-described manufacturing method, each of the p-type impurity and the n-type impurity is introduced into the lower layer portion of the semiconductor substrate 10 by a single ion implantation. In another example, each of the p-type impurity and the n-type impurity may be introduced into the lower layer portion of the semiconductor substrate 10 by multiple ion implantations, so that layers into which the p-type impurity is introduced and layers into which the n-type impurity is introduced are each formed as multi-stage diffusion layers. In this case, in the layers into which the p-type impurity is introduced, the concentration of the p-type impurity may be adjusted to be higher than that of the n-type impurity in the second portion farther from the lower surface of the semiconductor substrate 10, and in the layers into which the n-type impurity is introduced, the concentration of the n-type impurity may be adjusted to be higher than that of the p-type impurity in the first portion close to the lower surface of the semiconductor substrate 10. With this manufacturing method as well, it is possible to form the stacked portion of the n-type boundary layer 18 and the p-type boundary layer 19 in the boundary region 106 of the semiconductor substrate 10.

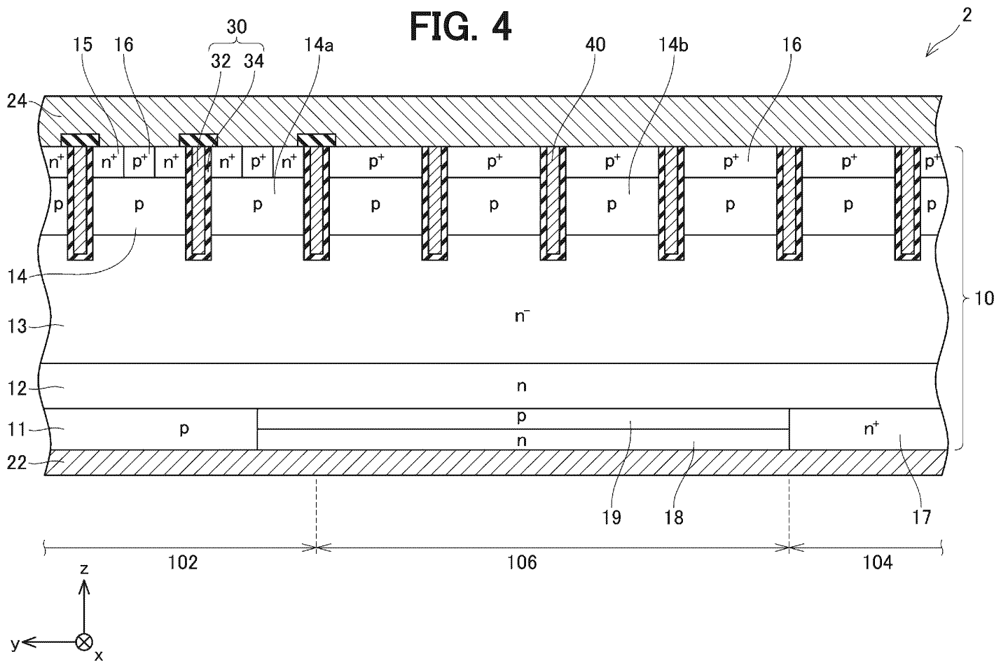

The semiconductor device 1 described above can be modified as follows. In a semiconductor device 2 shown in FIG. 4, the stacked portion of the n-type boundary layer 18 and the p-type boundary layer 19 is formed so as to extend from the boundary between the IGBT region 102 and the boundary region 106 into the IGBT region 102. A length by which the stacked portion of the n-type boundary layer 18 and the p-type boundary layer 19 extends from the boundary between the IGBT region 102 and the boundary region 106 into the IGBT region 102 may be a length that allows for manufacturing variations. Similarly, the stacked portion of the n-type boundary layer 18 and the p-type boundary layer 19 may be formed so as to be recessed from the boundary between the IGBT region 102 and the boundary region 106 toward the boundary region 106. In either case, the semiconductor device 2 can achieve the same effects and advantages as the semiconductor device 1.

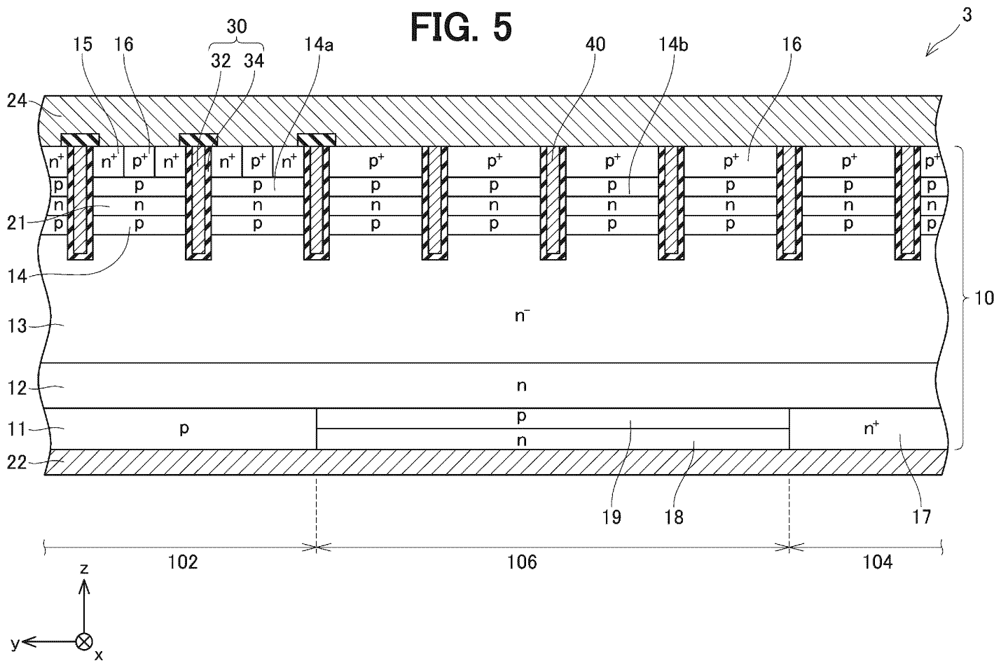

A semiconductor device 3 shown in FIG. 5 is characterized in that an n-type barrier layer 21 is disposed in the semiconductor substrate 10. The barrier layer 21 is disposed throughout the IGBT region 102, the boundary region 106, and the diode region 104 of the semiconductor substrate 10. The barrier layer 21 is embedded within the base layer 14 to divide the base layer 14 into upper and lower portions. The barrier layer 21 is formed by implanting ions of an n-type impurity toward the upper surface of the semiconductor substrate 10 using ion implantation techniques. The n-type impurity is not particularly limited, and may be, for example, phosphorus. An effective peak concentration of the n-type impurity in the barrier layer 21 may be lower than an effective peak concentration of the p-type impurity in the second base layer 14b. When the barrier layer 21 is disposed, it is possible to suppress hole injection from the base layer 14 during recovery operation. Accordingly, the semiconductor device 3 can have characteristics of low recovery loss.

Although specific examples of the present disclosure have been described in detail above, these are merely examples and do not limit the scope of claims. The techniques described in the claims include various changes and modifications of the specific examples illustrated above. In addition, the technical elements described in the present description or the drawings exhibit technical usefulness alone or in various combinations, and are not limited to the combinations described in the claims at the time of filing. In addition, the techniques illustrated in the present specification or drawings can achieve multiple purposes at the same time, and achieving one of the purposes itself has technical usefulness.

What is claimed is:

1. A reverse-conducting insulated gate bipolar transistor (IGBT) comprising:
a semiconductor substrate having an IGBT region, a diode region, and a boundary region located between the IGBT region and the diode region;
a lower electrode disposed on a lower surface of the semiconductor substrate; and
an upper electrode disposed on an upper surface of the semiconductor substrate, wherein
the semiconductor substrate includes:
a drift layer of a first conductivity type disposed throughout the IGBT region, the diode region, and the boundary region;
a base layer of a second conductivity type disposed throughout the IGBT region, the diode region, and the boundary region, and disposed above the drift layer;
an emitter layer of the first conductivity type disposed in the IGBT region, disposed above the base layer, and in contact with the upper electrode;
a collector layer of the second conductivity type disposed in the IGBT region, disposed below the drift layer, and in contact with the lower electrode;
a cathode layer of the first conductivity type disposed in the diode region, disposed below the drift layer, and in contact with the lower electrode;
a first conductivity type boundary layer of the first conductivity type disposed in the boundary region, disposed below the drift layer, and in contact with the lower electrode; and
a second conductivity type boundary layer of the second conductivity type disposed in the boundary region, and disposed between the first conductivity type boundary layer and the drift layer.

2. The reverse-conducting IGBT according to claim 1, wherein
a distribution of a first conductivity type impurity in a thickness direction of the semiconductor substrate is same in the cathode layer and a stacked portion of the first conductivity type boundary layer and the second conductivity type boundary layer, and
a distribution of a second conductivity type impurity in the thickness direction of the semiconductor substrate is same in the collector layer and the stacked portion of the first conductivity type boundary layer and the second conductivity type boundary layer.

3. The reverse-conducting IGBT according to claim 1, wherein
the base layer includes a first base layer disposed in the IGBT region and a second base layer disposed in the diode region and the boundary region, and
the second base layer has a lower concentration of a second conductivity type impurity than the first base layer.

4. The reverse-conducting IGBT according to claim 1, wherein
the semiconductor substrate further includes a barrier layer of the first conductivity type disposed throughout the IGBT region, the diode region, and the boundary region, and is embedded within the base layer.

5. The reverse-conducting IGBT according to claim 1, wherein
the semiconductor substrate further includes a buffer layer of the first conductivity type disposed throughout the IGBT region, the diode region, and the boundary region, and disposed between the drift layer and each of the collector layer, the cathode layer, and the second conductivity type boundary layer, and
the buffer layer has a higher concentration of a first conductivity type impurity than the drift layer.

6. The reverse-conducting IGBT according to claim 1, further comprising
a trench gate disposed in the IGBT region, and disposed within a trench that extends from the upper surface of the semiconductor substrate into the drift layer through the base layer.

7. The reverse-conducting IGBT according to claim 1, further comprising
a dummy trench gate disposed in the diode region and the boundary region, and disposed within a trench that extends from the upper surface of the semiconductor substrate into the drift layer through the base layer.

8. A manufacturing method of a reverse-conducting insulated gate bipolar transistor (IGBT) including a semiconductor substrate having an IGBT region, a diode region, and a boundary region located between the IGBT region and the diode region, the manufacturing method comprising:
a first ion implantation process of implanting second conductivity type impurity ions into portions of the semiconductor substrate corresponding to the IGBT region and the boundary region in a lower portion of the semiconductor substrate; and
a second ion implantation process of implanting first conductivity type impurity ions into portions of the semiconductor substrate corresponding to the diode region and the boundary region in the lower portion of the semiconductor substrate, wherein
a concentration of the second conductivity type impurity ions implanted in the first ion implantation process and a concentration of the first conductivity type impurity ions implanted in the second ion implantation process are adjusted in such a manner that the concentration of the first conductivity type impurity ions is higher than the concentration of the second conductivity type impurity ions at a first portion of the semiconductor substrate close to a lower surface of the semiconductor substrate, and the concentration of the second conductivity type impurity ions is higher than the concentration of the first conductivity type impurity ions at a second portion of the semiconductor substrate that is further from the lower surface of the semiconductor substrate than the first portion.

9. The manufacturing method according to claim 8, wherein
in the first ion implantation process, the second conductivity type impurity ions are implanted to a first depth from the lower surface of the semiconductor substrate,
in the second ion implantation process, the first conductivity type impurity ions are implanted to a second depth from the lower surface of the semiconductor substrate, and
the second depth is shallower than the first depth.
